(19) United States
(12) Patent Application Publication
(10) Pub. No.: US 2021/0143609 A1
(43) Pub. Date: May 13, 2021

(54) SEMICONDUCTOR OPTICAL DEVICE AND METHOD FOR PRODUCING SEMICONDUCTOR OPTICAL DEVICE

(71) Applicant: SUMITOMO ELECTRIC INDUSTRIES, LTD., Osaka (JP)

(72) Inventor: Takuo HIRATANI, Osaka-shi (JP)

(73) Assignee: SUMITOMO ELECTRIC INDUSTRIES, LTD., Osaka (JP)

(21) Appl. No.: 17/076,411

(22) Filed: Oct. 21, 2020

(30) Foreign Application Priority Data
Nov. 8, 2019 (JP) 2019-203453

(51) Int. Cl. H01S 5/12; H01S 5/10; H01S 5/125; H01S 5/068

(52) U.S. Cl. CPC H01S 5/1209; H01S 5/068; H01S 5/125; H01S 5/1014

(57) ABSTRACT

A semiconductor optical device includes a substrate containing silicon and having a waveguide, a first semiconductor element including a core layer formed of III-V group compound semiconductors and being bonded to the substrate, and a second semiconductor element including a diffraction grating and being bonded to the substrate, wherein the diffraction grating has a first semiconductor layer and a second semiconductor layer burying the first semiconductor layer, the first semiconductor layer and the second semiconductor layer are formed of III-V group compound semiconductors, and the diffraction grating reflects light propagating through the waveguide.

### CROSS-REFERENCE TO RELATED APPLICATION

This application is based upon and claims the benefit of priority of the prior Japanese Patent Application No. 2019-203453, filed on Nov. 8, 2019, the entire contents of which are incorporated herein by reference.

### FIELD

The present disclosure relates to a semiconductor optical device and a method for producing a semiconductor optical device.

### BACKGROUND

A technique of bonding a light-emitting device formed of compound semiconductors to an SOI (Silicon On Insulator) substrate having a waveguide formed thereon is known (for example, “Optics Express (OPTICS EXPRESS)” Shahram Keyvaninia et al., Vol. 21, No. 3, 3784-3792, 2013).

### SUMMARY

A semiconductor optical device according to the present disclosure includes a substrate containing silicon and having a waveguide, a first semiconductor element including a core layer formed of III-V group compound semiconductors and being bonded to the substrate, and a second semiconductor element including a diffraction grating and being bonded to the substrate. In this semiconductor optical device, the diffraction grating has a first semiconductor layer and a second semiconductor layer burying the first semiconductor layer. The first semiconductor layer and the second semiconductor layer are formed of III-V group compound semiconductors, and the diffraction grating reflects light propagating through the waveguide.

A method for producing a semiconductor optical device according to the present disclosure includes: a step for bonding a first semiconductor element including a core layer formed of III-V group compound semiconductors to a substrate containing silicon and having a waveguide; and a step for bonding a second semiconductor element including a diffraction grating to the substrate. In the present method for producing a semiconductor optical device, the diffraction grating includes a first semiconductor layer and a second semiconductor layer burying the first semiconductor layer, and the first semiconductor layer and the second semiconductor layer are formed of III-V group compound semiconductors.

### BRIEF DESCRIPTION OF THE DRAWINGS

FIG. 1A is a plan view illustrating a semiconductor optical device according to a first embodiment.

FIG. 1B is a cross-sectional view illustrating a semiconductor optical device.

FIG. 1C is a graph showing properties of a ring resonator.

FIG. 2A is a plan view enlarging vicinity of a semiconductor element.

FIG. 2B is a cross-sectional view illustrating a semiconductor element.

FIG. 3A is a plan view illustrating a method for producing of a semiconductor optical device.

FIG. 3B is a cross-sectional view illustrating a method for producing of a semiconductor optical device.

FIG. 4A is a plan view illustrating a method for producing of a semiconductor optical device.

FIG. 4B is a cross-sectional view illustrating a method for producing of a semiconductor optical device.

FIG. 5A is a plan view illustrating a method for producing of a semiconductor optical device.

FIG. 5B is a cross-sectional view illustrating a method for producing of a semiconductor optical device.

FIG. 6A is a plan view illustrating a method for producing of a semiconductor optical device.

FIG. 6B is a cross-sectional view illustrating a method for producing of a semiconductor optical device.

FIG. 7A is a plan view illustrating a method for producing of a semiconductor optical device.

FIG. 7B and FIG. 7C are cross-sectional views illustrating a method for producing of a semiconductor optical device.

FIG. 8A is a plan view illustrating a semiconductor optical device according to Comparative Example 1.

FIG. 8B is a cross-sectional view illustrating a diffraction grating.

FIG. 9A is a graph showing a calculation result of refractive index coupling coefficient in Comparative Embodiment 1.

FIG. 9B is a graph showing a calculation result of refractive index coupling coefficient in a first embodiment.

FIG. 10A is a graph illustrating reflection characteristics of diffraction grating according to Comparative Example 1.

FIG. 10B is a graph illustrating reflection characteristics of diffraction grating according to a first embodiment.

FIG. 11A is a graph illustrating reflection characteristics of diffraction grating according to Comparative Example 1.

FIG. 11B is a graph illustrating reflection characteristics of diffraction grating according to a first embodiment.

FIG. 12A is a plan view illustrating a semiconductor optical device 200 according to a second embodiment.

FIG. 12B is a plan view illustrating a semiconductor optical device 300 according to a third embodiment.

FIG. 12C is a plan view illustrating a semiconductor optical device 400 according to a fourth embodiment.

FIG. 13 is a plan view illustrating a semiconductor device according to a fifth embodiment.

FIG. 14A is a graph showing reflection characteristics in Comparative Example 2.

FIG. 14B is an enlarged view in the wavelength range of 1540 nm to 1560 nm.

FIG. 15A is a graph showing reflection characteristics in a fifth embodiment.

FIG. 15B is an enlarged view in the wavelength range of 1540 nm to 1560 nm.

### DESCRIPTION OF EMBODIMENTS

Waveguides, resonators, and diffraction gratings are formed on a SOI substrate. The resonator selects the wavelength of light, and the diffraction grating reflects light having the selected wavelength. The silicon (Si) layer of the SOI substrate is provided with recesses and projections, sometimes to function as a diffraction grating. The depth of the recesses and projections determines reflection characteristics of the diffraction grating. Since the difference in refractive index between the outside of the Si layer and the Si layer is large, reflection characteristics is greatly changed due to the variation in the depth of the recesses and projections. As a result, it becomes difficult to control a light output. Therefore, it is an object to provide a semiconductor optical device and a method for producing a semiconductor optical device capable of suppressing variation in reflection characteristics of a diffraction grating.

First, the contents of embodiments according to the present disclosure will be listed and described.

A semiconductor optical device according to an embodiment of the present disclosure includes: (1) a substrate containing silicon and having a waveguide; a first semiconductor element including a core layer formed of III-V group compound semiconductors and being bonded to the substrate; and a second semiconductor element including a diffraction grating and being bonded to the substrate. In the semiconductor optical device, the diffraction grating has a first semiconductor layer and a second semiconductor layer burying the first semiconductor layer. The first semiconductor layer and the second semiconductor layer are formed of III-V group compound semiconductors. The diffraction grating reflects light propagating through the waveguide. In the semiconductor optical device, since the change rate of reflection characteristics of the diffraction grating to the change in thickness of the first semiconductor layer is small, it is possible to suppress the variation of reflection characteristics.

(2) The first semiconductor layer includes gallium indium arsenide phosphorus layers disposed periodically. The second semiconductor layer may contain an indium phosphide layer. The rate of change in reflection characteristics of the diffraction grating due to a change in the thickness of the gallium indium arsenide phosphorus layers is small. Therefore, it is possible to suppress the variation of reflection characteristics of the diffraction grating.
(3) Two second semiconductor elements are bonded to the substrate, one of the two of the second semiconductor elements is optically coupled with one end portion of the first semiconductor element, and the other of the two of the second semiconductor elements is optically coupled with the other end portion of the first semiconductor element. Each reflectance of the two second semiconductor elements may be different from each other. Light reflected by the one of the two of the second semiconductor elements can be emitted from the other of the two of the second semiconductor elements.
(4) The substrate has a resonator located between the first semiconductor element and the one of the two of the second semiconductor elements. For light of a wavelength selected by the resonator, the reflectance of the one second semiconductor element of the two of the second semiconductor elements may be higher than the reflectance of the other second semiconductor element of the two of the second semiconductor elements. Thus, it is possible to reflect light of the wavelength selected by the resonator in the one second semiconductor elements and emit from the side of the other second semiconductor element.
(5) The resonator may include at least one ring resonator. The wavelength of light can be controlled by the ring resonator.
(6) The first semiconductor element and the second semiconductor element may have a tapered portion that is located on the waveguide and tapers along the extending direction of the waveguide. By having the tapered portion, light is less likely to be reflected at the end face of the semiconductor elements, and easily propagated to the diffraction grating. Therefore, optical loss is suppressed.
(7) The width of a portion of the waveguide overlapping with the diffraction grating, in a plan view, may be smaller than the width of a portion of the waveguide not overlapping with the diffraction grating. Thus, it is possible to increase refractive index coupling coefficient between the waveguide and the diffraction grating.
(8) The diffraction grating of the second semiconductor element may form an SG-DBR (Sampled Grating-Distributed Bragg Reflector).
(9) A method for producing a semiconductor optical device according to another embodiment of the present disclosure includes a step of bonding a first semiconductor element including a core layer of III-V group compound semiconductors to a substrate containing silicon and having a waveguide; and a step of bonding a second semiconductor element including a diffraction grating to the substrate. In this method for producing a semiconductor optical device, the diffraction grating has a first semiconductor layer and a second semiconductor layer burying the first semiconductor layer. The first semiconductor layer and the second semiconductor layer are formed of III-V group compound semiconductors. The change rate of reflection characteristics of the diffraction grating due to the change in the thickness of the first semiconductor layer is small. Therefore, it is possible to suppress the variation of reflection characteristics of the diffraction grating.
(10) The method for producing of a semiconductor optical device further includes a step of forming the second semiconductor element by forming a sacrificial layer, the first semiconductor layer and the second semiconductor layer; and a step of removing the sacrificial layer by etching. In the step of bonding the second semiconductor element, a surface of the second semiconductor element exposed by removing the sacrificial layer may be bonded to the substrate. In the second semiconductor element, since the surface exposed by removing the sacrificial layer is flat, bonding strength between the second semiconductor element and the substrate is improved.

### Details of the Embodiments According to the Present Disclosure

Specific examples of a semiconductor optical device and a method for producing a semiconductor optical device according to embodiments of the present disclosure will be described below with reference to the drawings. It should be understood that the present disclosure is not limited to these embodiments disclosed herein. The scope of the present disclosure is defined by the claims, and is intended to include all the modifications within the scope and meaning equivalent to the scope of the claims.

### First Embodiment

FIG. 1A is a plan view illustrating a semiconductor optical device 100 according to a first embodiment. As illustrated in FIG. 1A, the semiconductor optical device 100 has a substrate 10, a semiconductor element 30 (first semiconductor element), semiconductor elements 60 and 62 (second semiconductor elements). The semiconductor optical device 100 is a hybrid-type wavelength tunable laser diode using silicon photonics.

The substrate 10 is a SOI substrate including a silicon (Si) layer and a silicon dioxide (SiO₂) layer as described later. The substrate 10 has a side extending in the X-axis direction and a side extending in the Y-axis direction. Waveguides 12, 14 and 16, ring resonators 18 and 20 are provided on the surface of the substrate 10. In addition, the semiconductor elements 30, 60 and 62 are bonded to the surface of the substrate 10. The semiconductor element 30 is a laser diode for emitting laser light. The semiconductor elements 60 and 62 have a diffraction grating. The diffraction grating acts as a distributed Bragg reflector (DBR) that reflects laser light.

The waveguides and the ring resonators are exposed to air. The waveguides 12, 14 and 16 extend linearly along one side of, for example, the semiconductor optical device 100 along the X-axis. The waveguides 12, 14 and 16 are disposed to be spaced apart from each other in the Y-axis direction. The semiconductor element 30 is provided on the waveguide 12 and is in optical coupling with the waveguide 12. The semiconductor element 60 is provided on the waveguide 12 and is in optical coupling with the waveguide 12. The semiconductor element 62 is provided on the waveguide 16 and is in optical coupling with the waveguide 16. The semiconductor element 60 faces one end portion of the semiconductor element 30, and the semiconductor element 62 is located on the other end portion of the semiconductor element 30. Tapered portions are formed at both end portions of the semiconductor element 30, respectively, and these tapered portions are located on the waveguide. The semiconductor elements 60 and 62 each have a tapered portion at one end portion, and these tapered portions are located on the waveguide.

An electrode 21 is on the waveguide 12 and is on the other end portion of the semiconductor element 30, i.e., between the semiconductor element 30 and the semiconductor element 62. A ring resonator 18 is located between the waveguide 12 and the waveguide 14 and is optically coupled thereto. A ring resonator 20 is located between the waveguide 14 and the waveguide 16 and optically coupled with both the waveguides 14 and 16. The transmission properties of the ring resonators 18 and 20 are determined by the radii of curvature, refractive index and the like in each resonator. The radius of curvature of the ring resonator 18 differs from the radius of curvature of the ring resonator 20. Vernier effect using the two ring resonators 18 and 20 allows a particular wavelength to be selected as an oscillating wavelength. An electrode 22 is provided on the ring resonator 18. An electrode 24 is provided on the ring resonator 20. The electrodes 21, 22 and 24 serve as heaters.

FIG. 1C is a graph showing the properties of the ring resonators. In FIG. 1C, the vertical axis represents reflectance of light of the two ring resonators 18 and 20, and the horizontal axis represents the wavelength of light. Peaks of reflectance are periodically present with respect to the wavelength, as illustrated in the FIG. 1C. In an example of FIG. 1C, there is the largest peak near the wavelength of 1550 nm, and the height of the peak decreases as the wavelength moves away from 1550 nm. By adjusting voltages applied to the electrode 22 provided in the ring resonator 18 and the electrode 24 provided in the ring resonator 20, the temperatures of the ring resonators 18 and 20 vary. Temperatures of the ring resonators 18 and 20 change the refractive indices of the ring resonators 18 and 20 and can shift the position of the peaks. This makes it possible to vary the wavelength.

(Semiconductor element 30) FIG. 1B is a cross-sectional view illustrating the semiconductor optical device 100, illustrating a cross-section along a line A-A in FIG. 1A. As illustrated in FIG. 1B, the substrate 10 is formed by stacking a SiO₂ layer 11 and a Si layer 13 on a thick silicon substrate (Si substrate 19) in this order. The semiconductor element 30 is bonded to one surface of the Si-layer 13. The SiO₂ layer 11 is provided on a surface of the Si layer 13 opposite to another surface to which the semiconductor element 30 is bonded. The Si-layer 13 includes the waveguide 12 and a terrace 15. A groove is provided each on both sides of the waveguide 12, and the terrace 15 is located outside the groove.

The semiconductor element 30 includes a mesa 31 and a buried layer 40. The mesa 31 includes a contact layer 32, a core layer 34, a cladding layer 36 and a contact layer 38, which are sequentially stacked in the Z-axis and are located on the waveguide 12. The contact layer 32 of the semiconductor element 30 extends from the waveguide 12 to the terrace 15. The buried layer 40 is located on the contact layer 32 and buries both sides of the mesa 31. Insulating layers 42 and 44 are stacked on the top of the buried layer 40. The insulating layer 42 is formed of, for example, silicon nitride (Si₃N₄). The insulating layer 44 is formed of, for example, silicon oxynitride (SiON).

The insulating layers 42 and 44 have an opening on the mesa 31. An ohmic electrode 48 is provided on the contact layer 38 exposed from the opening. A metal layer 52 and an electrode 56 are stacked in this order on the top of the ohmic electrode 48. The ohmic electrode 48, the metal layer 52 and the electrode 56 form a p-type electrode. The metal layer 52 and the electrode 56 extend from the top surface of the mesa 31 to the end portion of the contact layer 32 on the Y-axis negative side of the mesa 31. The ohmic electrode 48 is formed by stacking titanium (Ti), platinum (Pt), and gold (Au), for example. The metal layer 52 is formed of, for example, titanium tungsten (TiW). The electrode 56 is made of gold, for example. An n-type electrode (not illustrated) is electrically connected to the contact layer 32.

The contact layer 32 is formed of, for example, n-type indium phosphide (n-InP). The core layer 34 has a multi quantum well structure (MQW) that includes well layers and barrier layers formed of, for example, undoped gallium indium arsenide (i-GaInAs). The cladding layer 36 is made of p-InP, for example. The contact layer 38 is made of p-GaInAs, for example. The buried layer 40 is formed of, for example, iron (Fe)-doped InP. The semiconductor element 30 may be formed of other semiconductors than the above. The semiconductor element 30 has an optical gain, and emits laser light when a current is injected to the semiconductor element 30.

(Semiconductor Element 62)

FIG. 2A is a plan view illustrating the semiconductor element 62. As illustrated in FIG. 2A, the semiconductor element 62 has a diffraction grating 64 and a tapered portion 66. The tapered portion 66 is located on the waveguide 16 of the substrate 10 and has a tapered shape along the extending direction of the waveguide 16. In the waveguide 16, the width W1 of a portion where the diffraction grating 64 and the waveguide 16 overlap with each other is, for example, 0.5 In the waveguide 16, the width W2 of another portion near the tapered portion 66 is larger than the width W1 of the portion where diffraction grating 64 and the waveguide 16 overlap with each other, and the width W2 is for example, 2 The width W3 of the diffraction grating 64 is larger than the width W1 by 8 μm or more, for example.

FIG. 2B is a cross-sectional view illustrating the semiconductor element 62, illustrating a cross-section along a line B-B of FIG. 2A. As illustrated in FIG. 2B, the semiconductor element 62 has gallium indium arsenide phosphorus (GaInAsP) layers 68 (first semiconductor layer) and an InP layer 70 (second semiconductor layer). The refractive index of the GaInAsP layers 68 differs from that of the InP layer 70. Each of the GaInAsP layers 68 is spaced apart from each other and is periodically disposed along the extending direction of the waveguide 16. The InP layer 70 buries the GaInAsP layers 68. The portion where the GaInAsP layers 68 and the InP layer 70 are disposed forms the diffraction grating 64. Based on the length L1 in the X-axis direction of the diffraction grating 64, the thickness T1 of the GaInAsP layers 68, the period X1 between the GaInAsP layers 68 adjacent to each other in the X-axis direction and the like, reflection characteristics of the diffraction grating 64 is determined. The period X1 is, for example, 0.3 The thickness T1 is, for example, 0.05 μm or more and 0.2 μm or less. The thickness T2 of the semiconductor element 62 is, for example, 0.1 μm or more and 0.25 μm or less.

The semiconductor element 60 has the same configuration as the semiconductor element 62. The number of the GaInAsP layers 68 of the semiconductor element 60 is less than the number of the GaInAsP layers 68 of the semiconductor element 62. Therefore, the reflectance of the semiconductor element 60 is lower than the reflectance of the semiconductor element 62.

When carriers are injected into the semiconductor element 30, the semiconductor element 30 emits laser light. The waveguides 12, 14 and 16, the ring resonators 18 and 20 form an optical path through which the emitted laser light of the semiconductor element 30 propagates. Vernier effect due to the difference in FSR (free spectral region) between the ring resonator 18 and ring resonator 20 are used to control the wavelength of light. Light with a controlled wavelength propagates through the waveguide 16 and enters the semiconductor element 62. The diffraction grating in the semiconductor element 62 reflects light having the above wavelength. Light reflected by the diffraction grating propagates through the waveguides 12, 14, 16, and the like. At least a portion of the propagating light is transmitted through the semiconductor element 60 and is emitted to the outside of the semiconductor optical device 100.

(Method for producing a semiconductor element) FIG. 3A, FIG. 4A, FIG. 5A, FIG. 6A and FIG. 7A are plan views illustrating a method for producing the semiconductor element 62. FIG. 3B, FIG. 4B, FIG. 5B, FIG. 6B, FIG. 7B and FIG. 7C are cross-sectional views illustrating the method for producing the semiconductor element 62, illustrating a cross-section along the line C-C of the corresponding plan view. Incidentally, the semiconductor element 60 is also manufactured in the same manner as the semiconductor element 62.

As illustrated in FIG. 3B, a sacrificial layer 74, an InP layer 70a, a GaInAsP layer 68, and an InP layer 70b are epitaxially grown in this order on a substrate 72 by, for example, Organometallic Vapor Phase Epitaxy (OMVPE). The substrate 72 is made of InP, for example, and the sacrificial layer 74 is made of AlInAs, for example.

After forming a resist pattern with electron beam lithography or the like, by dry etching of the InP layer 70b and the GaInAsP layer 68 using CH₄ and H₂ gases, InP layers 70b and GaInAsP layers 68 that are patterned as illustrated in FIG. 4A and FIG. 4B is formed.

As illustrated in FIG. 5A and FIG. 5B, another InP layer is epitaxially grown on the patterned InP layers 70b and GaInAsP layers 68 by OMVPE method or the like so as to be integrated with the InP layers 70a and 70b, and thus the InP layer 70 for burying the GaInAsP layer 68 is formed.

An opening 71 is formed in the InP layer 70 and the sacrificial layer 74 by conducting dry etching of these two layers as illustrated in FIG. 6A and FIG. 6B. The opening 71 is provided so as to surround the GaInAsP layers 68. The side surface of the sacrificial layer 74 and the top surface of the substrate 72 are exposed in the opening 71. As illustrated in FIG. 6A, in a plan view, the portion inside the opening 71 provided so as to surround GaInAsP layers 68 (diffraction grating side) and the portion outside the opening 71 are connected by bridges 73.

As illustrated in FIG. 7A and FIG. 7B, the sacrificial layer 74 is removed by wet etching. Thus, the semiconductor element 62 is formed, and the bottom surface 62a of the semiconductor element 62 is exposed. The semiconductor element 62 is supported by the bridges 73.

FIG. 7C is a cross-sectional view illustrating a step of bonding. As illustrated in FIG. 7C, a stamp 75 (PDMS, polydimethylsiloxane) picks up the semiconductor element 62 and places the semiconductor element 62 on the substrate 10 so that the bottom surface 62a of the semiconductor element 62 contacts the substrate 10. By pressurizing the semiconductor element 62 toward the substrate 10, the semiconductor element 62 is bonded to the substrate 10. The semiconductor element 60 is also formed using the same step as the semiconductor element 62 and is bonded to the substrate 10. After bonding, resist patterns are formed on the semiconductor elements 60 and 62, and the tapered portion 66 is formed by dry etching using methane/hydrogen gases (CH₄ and H₂).

The semiconductor element 30 is produced by growing semiconductor layers by OMVPE method or the like, the formation of the mesa 31 by etching, and the formation of electrodes by vapor deposition or the like. The semiconductor element 30 is also bonded to the substrate 10 using the stamp 75.

(Comparative Example 1) FIG. 8A is a plan view illustrating a semiconductor optical device 100C according to Comparative Example 1. As illustrated in FIG. 8A, the semiconductor optical device 100C does not have the semiconductor elements 60 and 62, but has diffraction gratings 80 and 81. Other configurations are the same as the semiconductor optical device 100.

FIG. 8B is a cross-sectional view illustrating the diffraction grating 81. As illustrated in FIG. 8B, the diffraction grating 81 is provided in the Si layer 13 of the substrate 10 and is made of recesses and projections arranged in the extending direction of the waveguide 16. The diffraction grating 80 also has the same configuration as the diffraction grating 81. The recesses and projections of the diffraction gratings 80 and 81 are exposed to air. Reflection characteristics of the diffraction gratings 80 and 81 is determined by the period of the recesses and projections, and the depth D of the recesses and projections and the like.

(Refractive index coupling coefficient) FIG. 9A is a graph showing a calculation result of refractive index coupling coefficient between the waveguide 16 and the diffraction grating 81 in Comparative Example 1. And, FIG. 9B is a graph showing a calculation result of the refractive index coupling coefficient between the waveguide 16 and the diffraction grating 81 in the first embodiment. In FIG. 9A and FIG. 9B, the point indicated by the triangle is an example where the width W1 of the waveguide 16 is 0.5 μm, the point indicated by the square is an example where the width W1 is 1 μm, and the point indicated by the circle is an example where the width W1 is 2 μm. The smaller the width W1 of the waveguide 16 is, the easier light propagates from the waveguide 16 to the diffraction grating, so that refractive index coupling coefficient between the waveguide 16 and the diffraction grating 81 is increased.

The horizontal axis of FIG. 9A represents the etching depth D of the Si layer 13, and the vertical axis represents the refractive index coupling coefficient between the waveguide 16 and the diffraction grating 81. As illustrated in FIG. 9A, in Comparative Example 1, when the etching depth D is increased, the refractive index coupling coefficient between the waveguide 16 and the diffraction grating 81 is also increased. For W1=0.5 μm, a change in etching depth D by 0.01 μm results in a change in refractive index coupling coefficient of about 700 cm⁻¹. Refractive index coupling coefficient of the diffraction grating 80 also exhibits properties similar to those of FIG. 9A.

The horizontal axis of FIG. 9B represents the thickness T2 of the diffraction grating 64 having the semiconductor element 62, and the vertical axis represents the refractive index coupling coefficient between the waveguide 16 and the diffraction grating 64. The thickness T2 of the diffraction grating 64 is changed by varying the thickness T1 of the GaInAsP layer 68 while fixing each thickness of the InP layer 70 on the upper side and the lower side of the GaInAsP layer 68 at 20 μm. As illustrated in FIG. 9B, in the first embodiment, when the thickness T2 increases, the refractive index coupling coefficient between the waveguide 16 and the diffraction grating 64 also increases. For W1=0.5 μm, a change in thickness T2 by 0.05 μm results in a change in refractive index coupling coefficient by about 500 cm⁻¹. The diffraction grating of the semiconductor element 60 also exhibits properties similar to those of FIG. 9B.

As illustrated in FIG. 8B, the Si-layer 13 is exposed to air. The difference in refractive index between Si and air is large. Therefore, as illustrated in FIG. 9A, the refractive index coupling coefficient of the diffraction grating 81 is also greatly changed with respect to the change in the etching depth D. Therefore, it is difficult to control the refractive index coupling coefficient. On the other hand, as illustrated in FIG. 2B, the diffraction grating 64 is formed by the GaInAsP layer 68 and the InP layer 70, and the GaInAsP layer 68 is buried in the InP layer 70. Since the difference in refractive index between the GaInAsP layer 68 and the InP layer 70 is small, the refractive index coupling coefficient gradually changes with respect to the change in the thickness T1 of the GaInAsP layer 68. The rate of change of the refractive index coupling coefficient of the diffraction grating 64 is about 1/10 of that of the diffraction grating 81. Therefore, by adjusting the thickness T1, it is possible to accurately control the refractive index coupling coefficient of the diffraction grating 64.

Since a refractive index coupling coefficient affects reflection characteristics of a diffraction grating, the reflection characteristics of the diffraction grating changes when the refractive index coupling coefficient changes. Reflection characteristics includes a reflectance as illustrated in FIG. 10A through 11B and a wavelength bandwidth (reflection bandwidth) in which a higher reflectance is obtained. The larger the refractive index coupling coefficient is, the higher the reflectance is and the wider the reflection bandwidth is. If the refractive index coupling coefficient is difficult to control, variation in reflection characteristics will occur. If the refractive index coupling coefficient can be precisely controlled, reflection characteristics can also be controlled stably.

FIG. 10A is a graph illustrating reflection characteristics of the diffraction grating 80 according to Comparative Example 1. FIG. 10B is a graph illustrating reflection characteristics of the diffraction grating 64 according to the first embodiment. The horizontal axis represents the wavelength of light. The vertical axis represents the reflectance. The length of the diffraction grating is 4 μm. The solid line in FIG. 10A is an example where the etching depth D of the Si layer 13 is 20 nm. The broken line is an example where the etching depth D is 30 nm. And, the dotted line is an example where the etching depth D is 40 nm. The solid line in FIG. 10B is an example where the thickness T2 of the diffraction grating 64 is 220 nm. The broken line is an example where the thickness T2 is 230 nm. And, the dotted line is an example where the thickness T2 is 240 nm. As in the case of FIG. 9B, the thickness T2 of the diffraction grating 64 is changed by varying the thickness T1 of the GaInAsP layer 68 and fixing each thickness of the InP layer 70 on the upper side and the lower side of the GaInAsP layer 68. A s illustrated in FIG. 10A and FIG. 10B, reflectance is maximized around the wavelength of 1550 nm in both cases, and reflectance gradually decreases as the wavelength moves away from 1550 nm.

As illustrated in FIG. 10A, in Comparative Example 1, as the etching depth D increases, the reflectance increases. The reflectance changes by about 20% as the etching depth D changes by 10 nm. The reflectance differs by about 40% between the example of D=20 nm and the example of D=40 nm. On the other hand, as illustrated in FIG. 10B, the reflectance is increased when the thickness T2 is increased in the first embodiment. The change in reflectance due to the change in thickness T2 by 20 nm is 10% or less. That is, the rate of change in reflectance with respect to the change in the thickness T2 of the GaInAsP layers 68 is smaller than the rate of change in reflectance in Comparative Example 1. Therefore, variation of the reflectance is suppressed.

FIG. 11A is a graph illustrating reflection characteristics of the diffraction grating 81 according to Comparative Example 1. FIG. 11B is a graph illustrating reflection characteristics of the diffraction grating 64 according to the first embodiment. The length of the diffraction grating is 30 μm. Both cases have a wavelength bandwidth (reflection bandwidth) with high reflectance.

As illustrated in FIG. 11A, the reflection bandwidth becomes wider as the etching depth D decreases in Comparative Example 1. In the etching depth D=40 nm, the reflection bandwidth is located approximately between 1540 nm and 1560 nm. In the etching depth D=30 nm, the reflection bandwidth is located approximately between 1530 nm and 1570 nm. In the etching depth D=20 nm, the reflection bandwidth is located approximately between 1520 nm and 1580 nm. When the etching depth D changes by 10 nm, the reflection bandwidth changes by about 20 nm.

As illustrated in FIG. 11B, the reflection bandwidth becomes wider as the thickness T2 decreases in the first embodiment. When the thickness T2 changes by 20 nm, the reflection bandwidth changes by about 2 nm. The rate of change of the reflection bandwidth in the first embodiment is smaller than that in Comparative Example 1. Therefore, variation of the reflection bandwidth is suppressed.

According to Comparative Example 1, when the variation occurs in the etching depth D of the Si layer 13, the refractive index coupling coefficient is changed significantly as illustrated in FIG. 9A. As a result, as illustrated in FIG. 10A and FIG. 11A, the reflectance and the reflection bandwidth also vary greatly. As illustrated in FIG. 8A, the two diffraction gratings 80 and 81 are formed by etching the Si-layer 13. Since it is difficult to control the etching depth D of each of the diffraction gratings 80 and 81 formed at different locations of the Si layer 13 to a desired depth, variation occurs in reflection characteristics of the diffraction gratings 80 and 81.

On the other hand, according to the first embodiment, the semiconductor elements 30, 60 and 62 are bonded to the substrate 10, and the semiconductor elements 60 and 62 have the diffraction grating 64. As illustrated in FIG. 2B, the diffraction grating 64 is formed of the GaInAsP layer 68 and the InP layer 70 burying the GaInAsP layer 68. Since the difference in refractive index between these layers is small, as illustrated in FIG. 9B, the rate of change of the refractive index coupling coefficient with respect to the change of the thickness T1 of the GaInAsP layers 68 is small. Therefore, as illustrated in FIG. 10B and FIG. 11B, variations in the reflectance and the reflection bandwidth is also reduced. That is, even when the variation in the thickness of the GaInAsP layers 68 occurs, it is possible to suppress the variation in reflection characteristics of the diffraction grating 64.

The diffraction grating 64 is formed of GaInAsP layers 68 that are periodically disposed and the InP layer 70 that buries the GaInAsP layers 68. Reflection characteristics of the diffraction grating 64 is determined, for example, by the number of layers and the thickness T1 of the GaInAsP layers 68. The rate of change of the refractive index coupling coefficient and the reflection characteristics due to the change of the thickness T1 is smaller than that of Comparative Example 1. Therefore, it is possible to suppress the variation of the reflection characteristics of the diffraction grating 64. For example, the thickness T1 of the GaInAsP layers 68 is controlled by adjusting the flow rate of the source gases and the growth time in OMVPE method.

The difference in refractive index between the III-V group compound semiconductor of the diffraction grating 64 and Si of the substrate 10 in the first embodiment is smaller than the difference in refractive index between air and Si in Comparative Example 1. Therefore, a large refractive index coupling coefficient such as 1000 cm⁻¹ or more can be obtained, and a sufficiently wide reflection bandwidth can be obtained. Further, in Comparative Example 1, the diffraction grating of the Si layer 13 is exposed to air, and the distribution of the refractive index is asymmetric in the vertical direction (axial direction). Therefore, the scattering loss of light is increased. Since the GaInAsP layer 68 is buried in the InP layer 70 in the first embodiment, the distribution of the refractive index in the diffraction grating 64 is symmetrical in the vertical direction (axial direction). Therefore, it is possible to suppress the scattering loss. Note that the semiconductor elements 60 and 62 may be formed of III-V group compound semiconductors other than GaInAsP and InP, and are preferably formed of materials that are less likely to absorb light emitted from the semiconductor element 30.

Two semiconductor elements 60 and 62 are bonded to the substrate 10. The semiconductor element 60 is in optical coupling with the X-axis negative end of semiconductor element 30. The semiconductor element 62 is in optical coupling with the X-axis positive end of the semiconductor element 30. The reflectance of the semiconductor element 62 is higher than reflectance of the semiconductor element 60. A part of light reflected by the semiconductor element 62 passes through the semiconductor element 60 and is emitted. To increase the reflectance of the semiconductor element 62, for example, it is sufficient to increase the length L1 in the X-axis direction of the diffraction grating than the semiconductor element 60 and to increase the number of the GaInAsP layers 68.

Two ring resonators 18 and 20 are provided between the semiconductor element 30 and the semiconductor element 62. The ring resonators 18 and 20 have properties illustrated in FIG. 1C. And, an oscillation wavelength can be selected by these resonators. The diffraction grating 64 of the semiconductor element 62 has a higher reflectance such as 100% for light having the wavelength selected by the ring resonator 18 and 20. Further, the diffraction grating 64 of the semiconductor element 60 has a reflectance such as about 30% for light having the selected wavelength, partially reflects light, and partially transmits light. Therefore, light emitted by the semiconductor element 30 is reflected by the semiconductor element 62. It is possible to emit light transmitted through the semiconductor element 60 to the outside of the semiconductor optical device 100. The semiconductor optical device 100 may be provided with a resonator other than the ring resonator, or alternatively an optical circuit for at least varying the wavelength of light.

As illustrated in FIG. 2A, the semiconductor element 62 has a tapered portion 66 that is located on the waveguide 16 and tapers along the extending direction of the waveguide 16. The semiconductor element 60 likewise has the tapered portion 66. By providing the tapered portion 66, light is less likely to be reflected at the end face of the semiconductor elements 60 and 62, and thus light tends to propagate to the diffraction grating 64. Therefore, optical loss is suppressed. The semiconductor elements 60 and 62 may be bonded to the substrate 10 after forming the tapered portion 66, or the tapered portion 66 may be formed after bonding. In order to align the tapered portion 66 with the waveguide, it is preferable to form the tapered portion 66 after bonding.

As illustrated in FIG. 2A, in the waveguide 16, the width W1 of the portion in the waveguide 16 where the diffraction grating 64 and the waveguide 16 overlap with each other is smaller than the width W2 of the portion in the waveguide 16 near the tapered portion 66 that does not overlap with the diffraction grating 64. This makes it easier for light to propagate to the diffraction grating 64, resulting in a higher refractive index coupling coefficient. The thickness T2 of the semiconductor elements 60 and 62 is, for example, 0.1 μm or more and 0.25 μm or less. Although optical coupling loss is suppressed by thinning the semiconductor elements 60 and 62, refractive index coupling coefficient is reduced. As described above, it is preferable to reduce the width W1 of the waveguide 16 to increase the refractive index coupling coefficient. The width W1 of the waveguide 16 is preferably 0.5 μm or more and 1.5 μm or less, for example.

The width W3 of the semiconductor elements 60 and 62 (the width of the diffraction grating 64) is greater than the width W1 of the waveguide by 8 μm or more, for example. In the diffraction grating 64, light spreads wider than the width W1 of the waveguide. Increasing the width W3 of the diffraction grating 64 increases the refractive index coupling coefficient. In addition, even if the center positions in the Y direction of the semiconductor elements 60 and 62 are shifted by a few micrometers from the center of the waveguide during bonding, the diffraction grating 64 still overlaps with the waveguide.

As illustrated in FIG. 7C from FIG. 7B, a so-called transfer printing is performed to take up the semiconductor element 62 after etching the sacrificial layer 74 and bond the semiconductor element 62 to the substrate 10. The surface 62a exposed by etching the sacrificial layer 74 becomes a bonding interface. Since the surface 62a is flat, bonding strength is improved.

### Second Embodiment

FIG. 12A is a plan view illustrating a semiconductor optical device 200 according to the second embodiment. Description of the same configuration as that of the first embodiment is omitted. In the semiconductor optical device 200, as illustrated in FIG. 12A, an asymmetric Mach-Zehnder interferometer 82 is provided between the ring resonator 20 and the semiconductor element 62. The Mach-Zehnder interferometer 82 includes waveguides 16 and 83 and an electrode 84. The waveguide 83 has a curved shape, and both ends of the waveguide 83 are connected to the waveguide 16. A part of light propagating through the waveguide 16 branches into the waveguide 83 and propagates, and merges again into the waveguide 16. By applying a voltage to the electrode 84 provided on the waveguide 83, the refractive index of the waveguide 83 changes. Light can be modulated by the Mach-Zehnder interferometer 82 to improve, for example, suppression ratio of neighboring modes. According to the second embodiment, similarly to the first embodiment, it is possible to suppress the variation of reflection characteristics of the diffraction grating 64.

### Third Embodiment

FIG. 12B is a plan view illustrating the semiconductor optical device 300 according to the third embodiment. Description of the same configuration as that of the first embodiment is omitted. In the semiconductor optical device 300, as illustrated in FIG. 12B, a ring resonator 18 is provided between the X-axis positive end portion of the semiconductor element 30 and the semiconductor element 62. The ring resonator 20 is provided between the X-axis negative end portion of the semiconductor element 30 and the semiconductor element 60. The ring resonator 20 is in optical coupling with the waveguides 12 and 23. The waveguide 23 has a curved shape. The semiconductor element 60 is provided on the waveguide 23 and is in optical coupling with the waveguide 23. According to the third embodiment, similarly to the first embodiment, it is possible to suppress the variation of reflection characteristics of the diffraction grating 64.

### Fourth Embodiment

FIG. 12C is a plan view illustrating the semiconductor optical device 400 according to the fourth embodiment. Description of the same configuration as that of the first embodiment is omitted. As illustrated in FIG. 12C, the semiconductor optical device 400 has one ring resonator 18. According to the fourth embodiment, similarly to the first embodiment, it is possible to suppress the variation of reflection characteristics of the diffraction grating 64. Compared to the first embodiment in which the wavelength is made variable by vernier effect of the two ring resonators, the variable range of the wavelength is narrower since the wavelength is controlled by one ring resonator 18 in the fourth embodiment.

As illustrated in the first to fourth embodiments, it is possible to use a ring resonator as a resonator for selecting a lasing wavelength. The number of ring resonators is at least one and may be one, two, or three or more. A resonator other than the ring resonator may be provided.

### Fifth Embodiment

FIG. 13 is a plan view illustrating a semiconductor element 62 according to the fifth embodiment. The semiconductor element 62 has diffraction gratings 64 aligned in the X-axis. The diffraction gratings 64 forms an SG-DBR (Sampled Grating-Distributed Bragg Reflector) section. The length L1 of each diffraction grating 64 is, for example, 10 μm, and the period L2 between each diffraction grating 64 is, for example, 100 μm. The number of the diffraction gratings 64 is, for example, six. The semiconductor element 60 also has an SG-DBR section. The semiconductor elements 60 and 62 with the SG-DBR areas are bonded to the substrate 10.

FIG. 14A is a view illustrating the reflection characteristics in Comparative Embodiment 2, and FIG. 14B is an enlarged view in the wavelength range of 1540 nm to 1560 nm. In Comparative Example 2, diffraction gratings formed by recesses and projections as illustrated in FIG. 8B on the Si layer 13 of the substrate 10 are arranged, providing an SG-DBR section. The solid line is an example where the etching depth D is 10 nm, and the broken line is an example where the etching depth D is 20 nm. FIG. 15A is a graph showing the reflection characteristics in the fifth embodiment, and FIG. 15B is an enlarged view in the wavelength range of 1540 nm to 1560 nm. The solid line indicates an example in which the thickness T1 of the GaInAsP layer 68 is 90 nm, and the broken line indicates an example in which the thickness T1 of the GaInAsP layer 68 is 100 nm. In Comparative Example 2 and the fifth embodiment, the length of each diffraction grating is 10 the period between each diffraction grating is 100 and the number of diffraction gratings is six.

As illustrated in FIG. 14A, in Comparative Example 2, when the etching depth D is changed from 10 nm to 20 nm, the reflectance in an unwanted wavelength bandwidth, for example, in the vicinity of 1520 nm and 1580 nm, increases. Further, as illustrated in FIG. 14B, the reflection bandwidth is changed. The ring resonators 18 and 20 reduce the reflectance for light having a selected wavelength, and the output of light having a desired wavelength is reduced.

As illustrated in FIG. 15A, the change in reflectance when the thickness T1 of the GaInAsP layer 68 is changed from 90 nm to 100 nm in the second embodiment is smaller than that in Comparative Example 2. Further, as illustrated in FIG. 15B, the amount of shifting of the reflection bandwidth is also about several nanometers, which is smaller than that in Comparative Example 2. Therefore, since the reflectance for light having a wavelength selected by the ring resonators 18 and 20 is higher, it is possible to output light having a desired wavelength.

Although the embodiments of the present invention have been described above in detail, the present invention is not limited to the specific embodiments, and various modifications and variations are possible within the scope of the gist of the present invention described in the claims.

What is claimed is:

1. A semiconductor optical device comprising:
a substrate containing silicon and having a waveguide;
a first semiconductor element including a core layer formed of III-V group compound semiconductors and being bonded to the substrate; and
a second semiconductor element including a diffraction grating and being bonded to the substrate,
wherein the diffraction grating has a first semiconductor layer and a second semiconductor layer burying the first semiconductor layer,
the first semiconductor layer and the second semiconductor layer are formed of III-V group compound semiconductors, and
the diffraction grating reflects light propagating through the waveguide.

2. The semiconductor optical device according to claim 1, wherein the first semiconductor layer comprises gallium indium arsenide phosphorous layers disposed periodically, and the second semiconductor layer comprises an indium phosphide layer.

3. The semiconductor optical device according to claim 1, wherein two of the second semiconductor elements are bonded to the substrate; one of the two of the second semiconductor elements is optically coupled with one end portion of the first semiconductor element; other of the two of the second semiconductor elements is optically coupled with other end portion of the first semiconductor element; and each reflectance of the two of the second semiconductor elements is different from each other.

4. The semiconductor optical device according to claim 3, wherein the substrate has a resonator located between the first semiconductor element and the one of the two of the second semiconductor elements, for light of a wavelength selected by the resonator, reflectance of the one of the two of the second semiconductor elements is higher than reflectance of the other of the two of the second semiconductor elements.

5. The semiconductor optical device according to claim 4, wherein the resonator comprises at least one ring resonator.

6. The semiconductor optical device according to claim 1, wherein the first semiconductor element and the second semiconductor element have a tapered portion that is located on the waveguide and tapers along an extending direction of the waveguide.

7. The semiconductor optical device according to claim 1, wherein a width of a portion of the waveguide overlapping with the diffraction grating in a plan view is smaller than a width of a portion of the waveguide not overlapping with the diffraction grating.

8. The semiconductor optical device according to claim 1, wherein the diffraction grating of the second semiconductor element forms a Sampled Grating-Distributed Bragg Reflector.

9. A method for producing a semiconductor optical device comprising:
a step of bonding a first semiconductor element including a core layer of III-V group compound semiconductors to a substrate containing silicon and having a waveguide; and
a step of bonding a second semiconductor element including a diffraction grating to the substrate,
wherein the diffraction grating has a first semiconductor layer and a second semiconductor layer burying the first semiconductor layer, and
the first semiconductor layer and the second semiconductor layer are formed of III-V group compound semiconductors.

10. The method for producing of a semiconductor optical device according to claim 9, further comprising:
a step of forming the second semiconductor element by forming a sacrificial layer, the first semiconductor layer and the second semiconductor layer; and
a step of removing the sacrificial layer by etching,
wherein in the step of bonding the second semiconductor element, a surface of the second semiconductor element exposed by removing the sacrificial layer is bonded to the substrate.
